(19) United States
(12) Patent Application Publication
(10) Pub. No.: US 2026/0362900 A1
(43) Pub. Date: Nov. 12, 2026

(54) DISPLAY DEVICE AND ELECTRONIC DEVICE

(71) Applicant: SAMSUNG DISPLAY CO., LTD., YONGIN-SI (KR)

(72) Inventors: Kyung Bae KIM, Yongin-si (KR); Dong Woo KIM, Yongin-si (KR); Gyung Soon PARK, Yongin-si (KR); Yong Hee LEE, Yongin-si (KR)

(21) Appl. No.: 19/653,226

(22) Filed: Apr. 21, 2026

(30) Foreign Application Priority Data
May 7, 2025 (KR) 10-2025-0058845

(51) Int. Cl. H10K 59/121; H10D 86/40; H10D 86/60; H10K 59/127; H10K 59/131

(52) U.S. Cl. CPC H10K 59/1213; H10D 86/441; H10D 86/60; H10K 59/1216; H10K 59/127; H10K 59/131

(57) ABSTRACT

A display device and an electronic device with improved image quality. The display device includes a main display panel comprising a wafer-based substrate, at least one sub-display panel comprising a glass-based substrate and adjacent to the main display panel, a first pixel arranged in a display area of the main display panel, and a second pixel arranged in a display area of the sub-display panel, the second pixel having a size larger than the first pixel. The first pixel includes a source-follower pixel circuit, and the second pixel includes a diode-connected pixel circuit.

### CROSS-REFERENCE TO RELATED APPLICATIONS

This application claims priority under 35 U.S.C. § 119 to and benefits from Korean Patent Application No. 10-2025-0058845 filed on May 7, 2025 in the Korean Intellectual Property Office, the entire contents of which is incorporated by reference herein.

### TECHNICAL FIELD

The disclosure relates to a display device with improved image quality and an electronic device.

### DISCUSSION OF THE RELATED ART

An organic light-emitting display apparatus includes display elements (e.g., organic light-emitting elements) having luminance varying depending on electric current.

### SUMMARY

Embodiments of the disclosure provide a display device and an electronic device that includes the display device with improved image quality.

According to an embodiment of the present disclosure, there is provided a display device including a main display panel including a wafer-based substrate, at least one sub-display panel including a glass-based substrate and adjacent to the main display panel, a first pixel arranged in a display area of the main display panel, the first pixel includes a source-follower circuit, and a second pixel arranged in a display area of the sub-display panel, the second pixel includes a diode-connected pixel circuit, the second pixel having a size larger than the first pixel.

According to an embodiment of the disclosure, a number of transistors of the second pixel may be greater than a number of transistors of the first pixel.

According to an embodiment of the disclosure, the transistors of the first pixel may include a first transistor which is a driving transistor of the first pixel, and the transistors of the second pixel may include a first transistor which is a driving transistor of the second pixel.

According to an embodiment of the disclosure, the first transistor of the first pixel may be connected to another transistor of the first pixel in a source-follower configuration, and the first transistor of the second pixel may be connected to another transistor of the second pixel in a diode-connected configuration.

According to an embodiment of the disclosure, the first pixel may include a first transistor comprising a gate electrode connected to a first node, a source electrode connected to a second node, a drain electrode connected to a third node, and a body electrode connected to a driving voltage line, a second transistor comprising a gate electrode connected to a first gate line, a source electrode connected to a data line, a drain electrode connected to the first node, and a body electrode connected to the driving voltage line, a third transistor comprising a gate electrode connected to an emission control line, a source electrode connected to the driving voltage line, a drain electrode connected to the second node, and a body electrode connected to the driving voltage line, a fourth transistor comprising a gate electrode connected to a second gate line, a source electrode connected to the third node, a drain electrode connected to an initialization voltage line, and a body electrode connected to the driving voltage line, a first capacitor connected between the first node and the second node, a second capacitor connected between the first node and a reference voltage line, a third capacitor connected between the first node and the third node, and a light-emitting element connected between the third node and a common voltage line.

According to an embodiment of the disclosure, the second pixel may include a first transistor comprising a gate electrode connected to a third node, a source electrode connected to a first node, and a drain electrode connected to a second node, a second transistor comprising a gate electrode connected to a first gate line, a source electrode connected to a data line, and a drain electrode connected to the first node, a third transistor comprising a gate electrode connected to a second gate line, a source electrode connected to the third node, and a drain electrode connected to the second node, a fourth transistor comprising a gate electrode connected to a third gate line, a source electrode connected to the third node, and a drain electrode connected to a first initialization voltage line, a fifth transistor comprising a gate electrode connected to an emission control line, a source electrode connected to a driving voltage line, and a drain electrode connected to the first node, a sixth transistor comprising a gate electrode connected to the emission control line, a source electrode connected to the second node, and a drain electrode connected to a fourth node, a seventh transistor comprising a gate electrode connected to a fourth gate line, a source electrode connected to the fourth node, and a drain electrode connected to a second initialization voltage line, an eighth transistor comprising a gate electrode connected to the fourth gate line, a source electrode connected to a bias voltage line, and a drain electrode connected to the first node, a capacitor connected between the third node and the driving voltage line, and light-emitting element connected between the fourth node and a common voltage line.

According to an embodiment of the disclosure, the main display panel may include a first side extended in a first direction and a second side adjacent to the first side and extended in a second direction intersecting an extension direction of the first side.

According to an embodiment of the disclosure, the at least one sub-display panel may include a first sub-display panel and a second sub-display panel adjacent to the main display panel.

According to an embodiment of the disclosure, the first sub-display panel may be located on the first side of the main display panel and extends in the first direction, and the second sub-display panel may be located on the second side of the main display panel and extends in the second direction.

According to an embodiment of the disclosure, a first sub-circuit board may be connected to the first sub-display panel to overlap a first side of the first sub-display panel, and a second sub-circuit board may be connected to the second sub-display panel to overlap a first side of the second sub-display panel.

According to an embodiment of the disclosure, the first side of the first sub-display panel may extend in the first direction, and the first side of the second sub-display panel may extend in the second direction.

According to an embodiment of the disclosure, a length of the first side of the first sub-display panel may be substantially equal to a sum of a length of the first side of the main display panel and a length of a second side of the second sub-display panel, and the second side of the second sub-display panel may be adjacent to the first side of the second sub-display panel and extends in the first direction.

According to an embodiment of the disclosure, a second side of the first sub-display panel may face the first side of the first sub-display panel, and the second side of the first sub-display panel may be in contact with the first side of the main display panel.

According to an embodiment of the disclosure, a third side of the main display panel may face the second side of the main display panel, a third side of the first sub-display panel may be arranged in a same line as the third side of the main display panel, an extension line of the second side of the main display panel may be located between the third side of the first sub-display panel and a fourth side of the first sub-display panel to overlap the first sub-display panel, and the fourth side of the first sub-display panel may face the third side of the first sub-display panel.

According to an embodiment of the disclosure, a second side of the second sub-display panel may face the first side of the second sub-display panel, and the second side of the second sub-display panel may be in contact with the second side of the main display panel.

According to an embodiment of the disclosure, a fourth side of the main display panel may face the first side of the main display panel, a third side of the second sub-display panel may be arranged in a same line as the first side of the main display panel, an extension line of the fourth side of the main display panel may be located between the third side of the second sub-display panel and a fourth side of the second sub-display panel to overlap the second sub-display panel, and the fourth side of the second sub-display panel may face the third side of the second sub-display panel.

According to an embodiment of the disclosure, there is provided an electronic device including a display device for providing a display screen, the display device including a main display panel including a wafer-based substrate, at least one sub-display panel including a glass-based substrate and adjacent to the main display panel, a first pixel arranged in a display area of the main display panel, the first pixel includes a source-follower pixel circuit, and a second pixel arranged in a display area of the sub-display panel, the second pixel includes a diode-connected pixel circuit, the second pixel having a size larger than the first pixel.

According to an embodiment of the disclosure, a number of transistors of the second pixel may be greater than a number of transistors of the first pixel.

According to an embodiment of the disclosure, the transistors of the first pixel may include a first transistor which is a driving transistor of the first pixel, the transistors of the second pixel may include a first transistor which is a driving transistor of the second pixel, the first transistor of the first pixel may be connected to another transistor of the first pixel in a source-follower configuration, and the first transistor of the second pixel may be connected to another transistor of the second pixel in a diode-connected configuration.

According to an embodiment of the disclosure, the electronic device may include a smartphone, a tablet, a laptop computer, a TV, a monitor, smart glasses, a smart watch, a head-mounted display, and a display for vehicles.

According to an embodiment of the disclosure, the image quality of a display device and an electronic device can be improved.

For example, according to an embodiment of the disclosure, as a source-follower pixel circuit is formed on a main display panel including a wafer-based substrate, and a diode-connected pixel circuit is formed on a sub-display panel including a glass-based substrate, the difference between the luminance uniformity deviations of the main display panel and the luminance uniformity deviations of the sub-display panel is reduced, so that the image quality of the display device can be improved.

The effects of the disclosure are not necessarily limited to the above-described effects and other effects which are not described herein will become apparent to those skilled in the art from the following description.

### BRIEF DESCRIPTION OF THE DRAWINGS

The above and other aspects and features of the disclosure will become more apparent by describing in detail exemplary embodiments thereof with reference to the attached drawings, in which:

FIG. 1 is a plan view of a display device according to an embodiment of the disclosure.

FIG. 2 is a view showing a rear side of the display device of FIG. 1.

FIG. 3 is a plan view showing multiple display panels of FIG. 1 when they are separated and disassembled.

FIG. 4 is a cross-sectional view of the main display panel of FIG. 1.

FIG. 5 is a cross-sectional view of the first sub-display panel of FIG. 1.

FIG. 6 is an equivalent circuit diagram of a pixel of a display device according to an embodiment.

FIG. 7 is an equivalent circuit diagram of a pixel of a display device according to an embodiment.

FIG. 8 is a view for illustrating the effects achieved by a display device according to an embodiment.

FIG. 9 is a block diagram of an electronic device according to an embodiment of the disclosure.

FIGS. 10, 11 and 12 are views showing electronic devices according to a variety of embodiments of the disclosure.

### DETAILED DESCRIPTION OF EMBODIMENTS

The disclosure will now be described more fully hereinafter with reference to the accompanying drawings, in which embodiments of the disclosure are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

It will also be understood that when a layer is referred to as being "on" another layer or substrate, it can be directly on another layer or substrate, or intervening layers may also be present. The same reference numbers indicate the same components throughout the specification. In the attached figures, the thickness of layers and regions is exaggerated for clarity.

Although the terms "first", "second", etc. may be used herein to describe various elements, these elements should not be limited by these terms. These terms may be used to distinguish an element from another element. Thus, a first element discussed below may be termed a second element without departing from teachings of one or more embodiments. The description of an element as a "first" element might not require or imply the presence of a second element or other elements. The terms "first", "second", etc. may also be used herein to differentiate different categories or sets of elements. For conciseness, the terms "first", "second", etc. may represent "first-category (or first-set)", "second-category (or second-set)", etc., respectively.

Features of various embodiments of the disclosure may be combined partially or totally. As will be clearly appreciated by those skilled in the art, technically various interactions and operations are possible. Various embodiments can be practiced individually or in combination.

While each drawing may represent one or more particular embodiments of the disclosure, drawn to scale, such that the relative lengths, thicknesses, and angles can be inferred therefrom, it is to be understood that the disclosure is not necessarily limited to the relative lengths, thicknesses, and angles shown. Changes to these values may be made within the spirit and scope of the disclosure, for example, to allow for manufacturing limitations and the like.

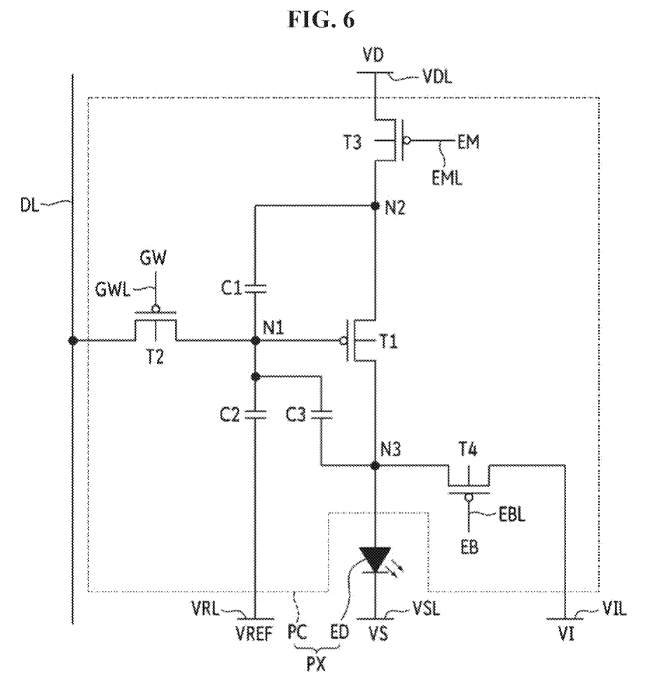

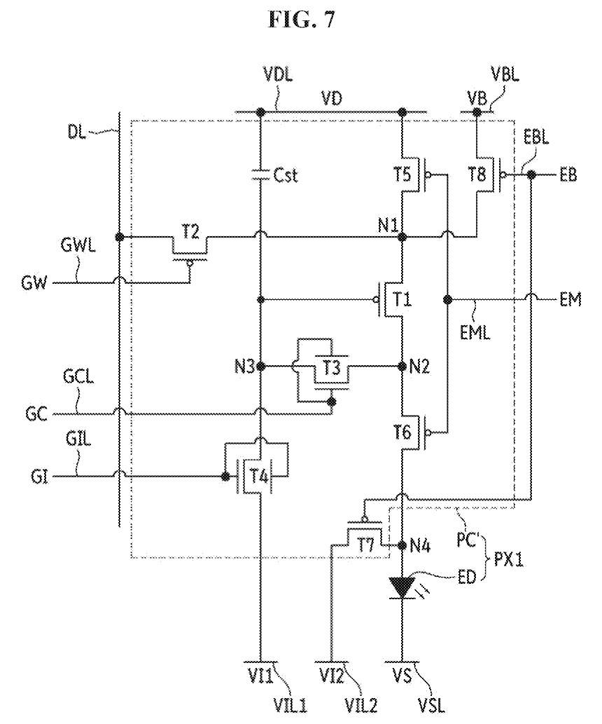

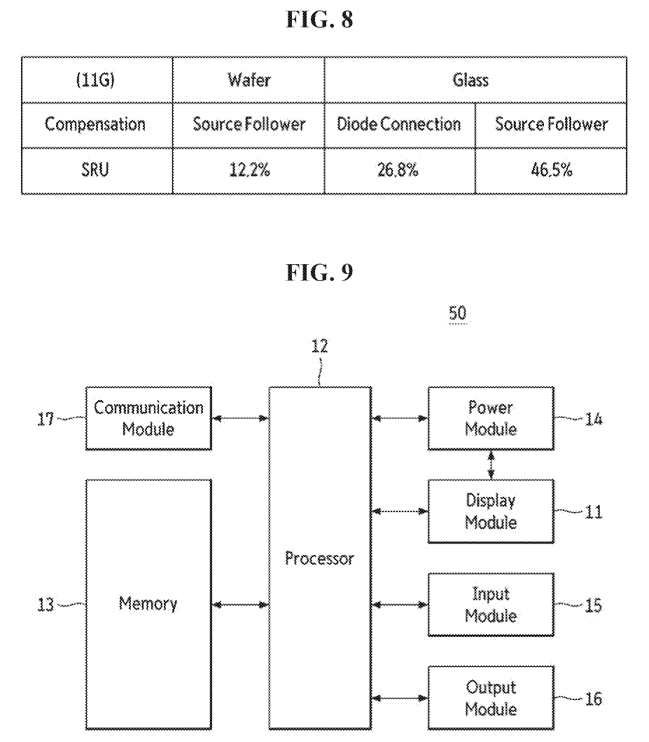

According to embodiments of the disclosure, there is provided a display device and an electronic device including the display device where the display device may include a main display panel including a wafer-based substrate and at least one sub-display panel including a glass-based substrate. The pixel circuits in the at least one sub-display panel are designed differently than in the main display panel. Specifically, it has been shown empirically (FIG. 8) that differences in luminance uniformity deviations between the main display panel and the sub-display panel are reduced if the pixel circuits in the sub-display panel are designed so that the driving transistor is diode connected as opposed to being source follower connected as in the pixel circuits of the main display panel. The diode connection design for a pixel circuit (FIG. 7) results in more transistors being disposed in a pixel circuit of the sub-display panels as compared to the pixel circuit of the main display panel that has the driving transistor source follower connected (FIG. 6), thereby decreasing resolution of the sub-display panels as compared to the main display panel. Nevertheless image quality of the overall display device is improved by reducing the difference in luminance uniformity deviations between the main display panel and the sub display panels.

Hereinafter, exemplary embodiments of the disclosure will be described in detail with reference to the accompanying drawings.

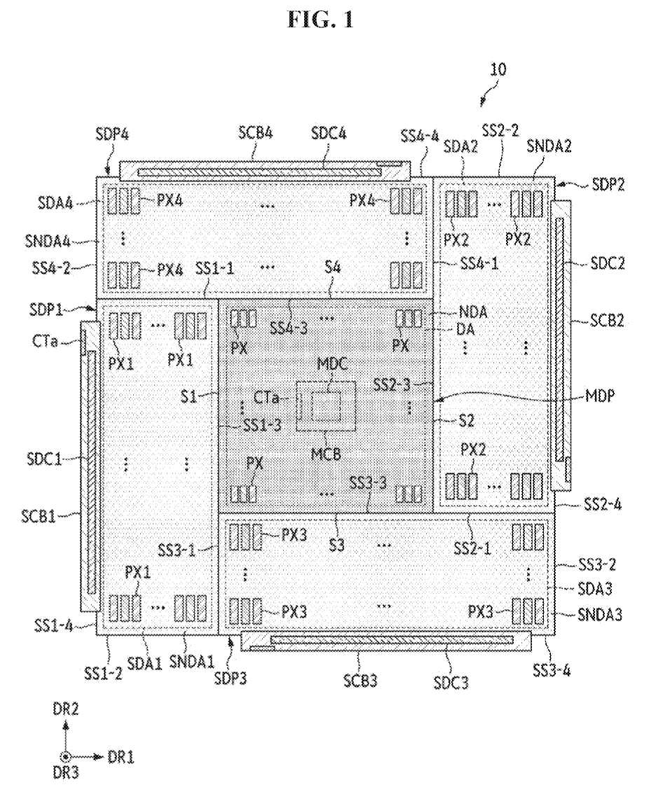

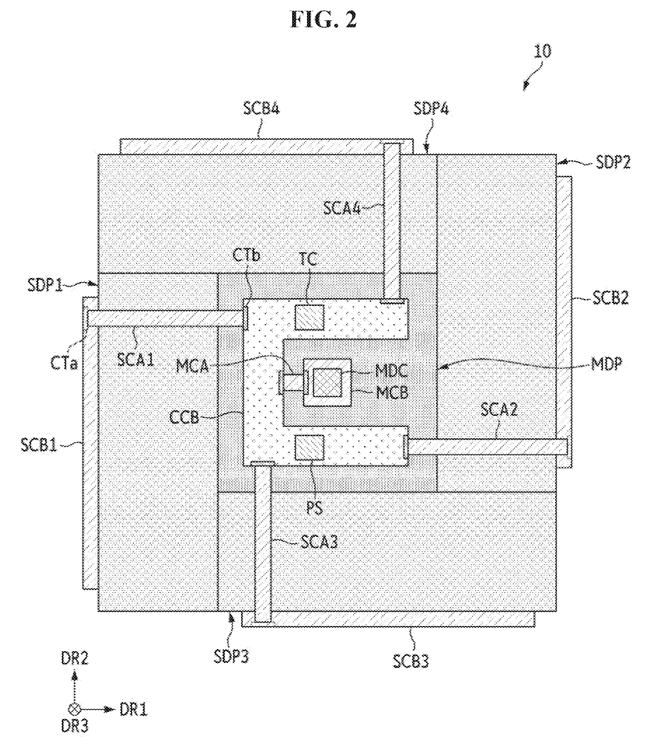

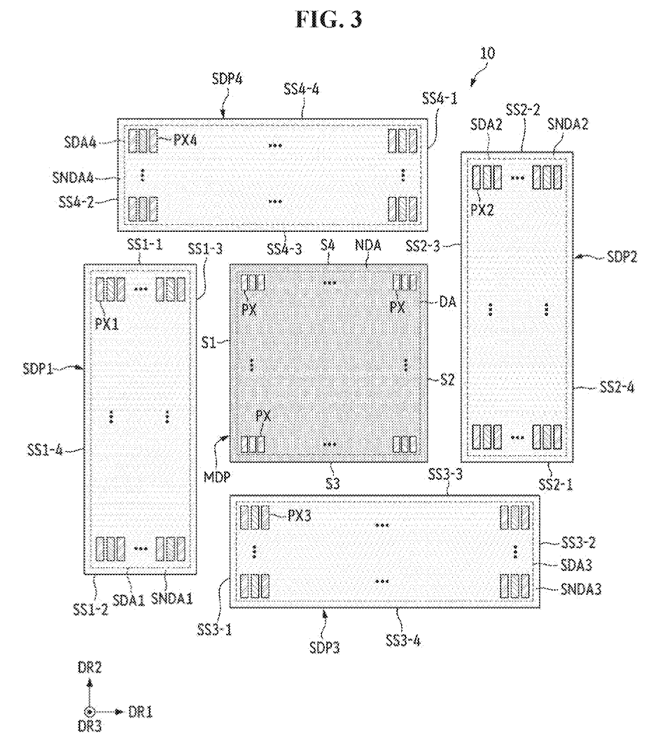

FIG. 1 is a plan view of a display device 10 according to an embodiment of the disclosure. FIG. 2 is a view showing a rear surface of the display device 10 of FIG. 1. FIG. 3 is a plan view showing multiple display panels of FIG. 1 when they are separated and disassembled. To the extent that the sub-circuit boards are not described in detail with respect to FIG. 3, it may be understood that the sub-circuit boards are at least similar to corresponding sub-circuit boards that has been described in FIG. 1 of the disclosure.

As shown in FIGS. 1-3, the display device 10 according to the embodiment may include multiple display panels (e.g., a main display panel MDP, a first sub-display panel SDP1, a second sub-display panel SDP2, a third sub-display panel SDP3, a fourth sub-display panel SDP4); a main circuit board MCB; a first sub-circuit board SCB1; a second sub-circuit board SCB2; a third sub-circuit board SCB3; a fourth sub-circuit board SCB4; a common circuit board CCB; a main driver circuit MDC; a first sub-driver circuit SDC1; a second sub-driver circuit SDC2; a third sub-driver circuit SDC3; a fourth sub-driver circuit SDC4; a main cable MCA; a first sub-cable SCA1; a second sub-cable SCA2; a third sub-cable SCA3; a fourth sub-cable SCA4; and multiple connectors CTa and CTb.

Multiple display panels (e.g., the main display panel MDP, the first sub-display panel SDP1, the second sub-display panel SDP2, the third sub-display panel SDP3, and the fourth sub-display panel SDP4) may be connected to one another to form a single unit display panel. The main display panel MDP, the first sub-display panel SDP1, the second sub-display panel SDP2, the third sub-display panel SDP3, and the fourth sub-display panel SDP4 may be connected to one another, for example, by an adhesive member.

The main display panel MDP may include a display area DA and a non-display area NDA. Multiple pixels PX may be arranged in the display area DA of the main display panel MDP. For example, the main display panel MDP may include an upper surface and a lower surface facing each other in a third direction DR3, and the pixels PX of the main display panel MDP may be arranged in the display area DA of the upper surface of the main display panel MDP. The pixels PX may provide light of different colors. For example, three pixels PX adjacent to one another in a direction (e.g., the first direction DR1) in the display area DA of the main display panel MDP may define a first pixel, a second pixel, and a third pixel, respectively. The first pixel among the three pixels PX may provide red light, the second pixel among the three pixels PX may provide green light, and the third pixel among the three pixels PX may provide blue light. Among the pixels PX of the main display panel MDP, a first pixel, a second pixel and a third pixel, which are arranged adjacent to each other, may form a unit pixel that displays a single unit image.

The main circuit board MCB may be arranged on the lower surface of the main display panel MDP. The main circuit board MCB may electrically connect to the lower surface of the main display panel MDP. For example, the main circuit board MCB may be connected to the pixels PX of the main display panel MDP through a via electrode that penetrates the substrate of the main display panel MDP.

The main driver circuit MDC may be arranged on the main circuit board MCB. The main driver circuit MDC may provide power signals and driving signals (e.g., a scan signal and a data voltage) required for driving the pixels PX of the main display panel MDP. The driving signals and the power signals from the main driver circuit MDC may be supplied to the pixels PX of the main display panel MDP through transmission lines and via electrodes of the main circuit board MCB.

The main display panel MDP may include a first side S1, a second side S2, a third side S3, and a fourth side S4. The first side S1 and the second side S2 may extend in a second direction DR2, and the third side S3 and the fourth side S4 may extend in the first direction DR1. The first side S1 may be adjacent to the third side S3 and the fourth side S4, and the third side S3 may be adjacent to the first side S1 and the second side S2. The first side S1 and the second side S2 may face each other in the first direction DR1, and the third side S3 and the fourth side S4 may face each other in the second direction DR2. The third side S3 may be located between an edge of the first side S1 and an edge of the second side S2, and the fourth side S4 may be located between the opposite edge of the first side S1 and the opposite edge of the second side S2.

The first sub-display panel SDP1, the second sub-display panel SDP2, the third sub-display panel SDP3 and the fourth sub-display panel SDP4 may be arranged on the first to fourth sides S1 to S4 of the main display panel MDP, respectively, to surround the main display panel MDP. For example, the first sub-display panel SDP1 may be located on the first side S1 of the main display panel MDP, the second sub-display panel SDP2 may be located on the second side S2 of the main display panel MDP, the third sub-display panel SDP3 may be located on the third side S3 of the main display panel MDP, and the fourth sub-display panel SDP4 may be located on the fourth side S4 of the main display panel MDP.

The first sub-display panel SDP1 may be in contact with the first side S1 of the main display panel MDP, the second sub-display panel SDP2 may be in contact with the second side S2 of the main display panel MDP, the third sub-display panel SDP3 may be in contact with the third side S3 of the main display panel MDP, and the fourth sub-display panel SDP4 may be in contact with the fourth side S4 of the main display panel MDP.

The first sub-display panel SDP1 may include a first side SS1-1, a second side SS1-2, a third side SS1-3, and a fourth side SS1-4. The first side SS1-1 and the second side SS1-2 may extend in the first direction DR1, and the third side SS1-3 and the fourth side SS1-4 may extend in the second direction DR2. The first side SS1-1 may be adjacent to the third side SS1-3 and the fourth side SS1-4, and the third side SS1-3 may be adjacent to the first side SS1-1 and the second side SS1-2. The first side SS1-1 and the second side SS1-2 may face each other in the second direction DR2, and the third side SS1-3 and the fourth side SS1-4 may face each other in the first direction DR1. The third side SS1-3 may be located between an edge of the first side SS1-1 and an edge of the second side SS1-2, and the fourth side SS1-4 may be located between the opposite edge of the first side SS1-1 and the opposite edge of the second side SS1-2. The length of the first side SS1-1 may be substantially equal to the length of the second side SS1-2, and the length of the third side SS1-3 may be substantially equal to the length of the fourth side SS1-4. The length of the third side SS1-3 may be greater than the length of the first side SS1-1. The third side SS1-3 of the first sub-display panel SDP1 may be in contact with the first side S1 of the main display panel MDP. The length of the third side SS1-3 of the first sub-display panel SDP1 may be greater than the length of the first side S1 of the main display panel MDP.

The first sub-display panel SDP1 may extend in the opposite direction of the second direction DR2 (hereinafter referred to as the second opposite direction) along the first side S1 of the main display panel MDP and on the first side S1. The extension line of the fourth side S4 of the main display panel MDP may be located on the same line as the first side SS1-1 of the first sub-display panel SDP1. The extension line of the third side S3 of the main display panel MDP may overlap the first sub-display panel SDP1 such that it intersects the extension direction of the first sub-display panel SDP1. For example, the extension line of the third side S3 of the main display panel MDP may be located between the first side SS1-1 and the second side SS1-2 of the first sub-display panel SDP1.

The second sub-display panel SDP2 may include a first side SS2-1, a second side SS2-2, a third side SS2-3, and a fourth side SS2-4. The first side SS2-1 and the second side SS2-2 may extend in the first direction DR1, and the third side SS2-3 and the fourth side SS2-4 may extend in the second direction DR2. The first side SS2-1 may be adjacent to the third side SS2-3 and the fourth side SS2-4, and the third side SS2-3 may be adjacent to the first side SS2-1 and the second side SS2-2. The first side SS2-1 and the second side SS2-2 may face each other in the second direction DR2, and the third side SS2-3 and the fourth side SS2-4 may face each other in the first direction DR1. The third side SS2-3 may be located between an edge of the first side SS2-1 and an edge of the second side SS2-2, and the fourth side SS2-4 may be located between the opposite edge of the first side SS2-1 and the opposite edge of the second side SS2-2. The length of the first side SS2-1 may be substantially equal to the length of the second side SS2-2, and the length of the third side SS2-3 may be substantially equal to the length of the fourth side SS2-4. The length of the third side SS2-3 may be greater than the length of the first side SS2-1. The third side SS2-3 of the second sub-display panel SDP2 may be in contact with the second side S2 of the main display panel MDP. The length of the third side SS2-3 of the second sub-display panel SDP2 may be greater than the length of the second side S2 of the main display panel MDP.

The second sub-display panel SDP2 may extend in the second direction DR2 along and on the second side S2 of the main display panel MDP. The extension line of the third side S3 of the main display panel MDP may be located on the same line as the first side SS2-1 of the second sub-display panel SDP2. The extension line of the fourth side S4 of the main display panel MDP may overlap the second sub-display panel SDP2 such that it intersects the extension direction of the second sub-display panel SDP2. For example, the extension line of the fourth side S4 of the main display panel MDP may be located between the first side SS2-1 and the second side SS2-2 of the second sub-display panel SDP2.

The third sub-display panel SDP3 may include a first side SS3-1, a second side SS3-2, a third side SS3-3, and a fourth side SS3-4. The first side SS3-1 and the second side SS3-2 may extend in the second direction DR2, and the third side SS3-3 and the fourth side SS3-4 may extend in the first direction DR1. The first side SS3-1 may be adjacent to the third side SS3-3 and the fourth side SS3-4, and the third side SS3-3 may be adjacent to the first side SS3-1 and the second side SS3-2. The first side SS3-1 and the second side SS3-2 may face each other in the first direction DR1, and the third side SS3-3 and the fourth side SS3-4 may face each other in the second direction DR2. The third side SS3-3 may be located between an edge of the first side SS3-1 and an edge of the second side SS3-2, and the fourth side SS3-4 may be located between the opposite edge of the first side SS3-1 and the opposite edge of the second side SS3-2. The length of the first side SS3-1 may be substantially equal to the length of the second side SS3-2, and the length of the third side SS3-3 may be substantially equal to the length of the fourth side SS3-4. The length of the third side SS3-3 may be greater than the length of the first side SS3-1. The third side SS3-3 of the third sub-display panel SDP3 may be in contact with the third side S3 of the main display panel MDP. The length of the third side SS3-3 of the third sub-display panel SDP3 may be greater than the length of the third side S3 of the main display panel MDP.

The third sub-display panel SDP3 may extend in the first direction DR1 along and on the third side S3 of the main display panel MDP. The extension line of the first side S1 of the main display panel MDP may be located on the same line as the first side SS3-1 of the third sub-display panel SDP3. The extension line of the second side S2 of the main display panel MDP may overlap the third sub-display panel SDP3 such that it intersects the extension direction of the third sub-display panel SDP3. For example, the extension line of the second side S2 of the main display panel MDP may be located between the first side SS3-1 and the second side SS3-2 of the third sub-display panel SDP3.

The fourth sub-display panel SDP4 may include a first side SS4-1, a second side SS4-2, a third side SS4-3, and a fourth side SS4-4. The first side SS4-1 and the second side SS4-2 may extend in the second direction DR2, and the third side SS4-3 and the fourth side SS4-4 may extend in the first direction DR1. The first side SS4-1 may be adjacent to the third side SS4-3 and the fourth side SS4-4, and the third side SS4-3 may be adjacent to the first side SS4-1 and the second side SS4-2. The first side SS4-1 and the second side SS4-2 may face each other in the first direction DR1, and the third side SS4-3 and the fourth side SS4-4 may face each other in the second direction DR2. The third side SS4-3 may be located between an edge of the first side SS4-1 and an edge of the second side SS4-2, and the fourth side SS4-4 may be located between the opposite edge of the first side SS4-1 and the opposite edge of the second side SS4-2. The length of the first side SS4-1 may be substantially equal to the length of the second side SS4-2, and the length of the third side SS4-3 may be substantially equal to the length of the fourth side SS4-4. The length of the third side SS4-3 may be greater than the length of the first side SS4-1. The third side SS4-3 of the fourth sub-display panel SDP4 may be in contact with the fourth side S4 of the main display panel MDP. The length of the third side SS4-3 of the fourth sub-display panel SDP4 may be greater than the length of the fourth side S4 of the main display panel MDP.

The fourth sub-display panel SDP4 may extend in the opposite direction of the first direction DR1 (hereinafter referred to as first opposite direction) along the fourth side S4 of the main display panel MDP and on the fourth side S4. The extension line of the second side S2 of the main display panel MDP may be located on the same line as the first side SS4-1 of the fourth sub-display panel SDP4. The extension line of the first side S1 of the main display panel MDP may overlap the fourth sub-display panel SDP4 such that it intersects the extension direction of the fourth sub-display panel SDP4. For example, the extension line of the first side S1 of the main display panel MDP may be located between the first side SS4-1 and the second side SS4-2 of the fourth sub-display panel SDP4.

The first side SS1-1 of the first sub-display panel SDP1 may be in contact with the third side SS4-3 of the fourth sub-display panel SDP4, and the third side SS1-3 of the first sub-display panel SDP1 may be in contact with the first side S1 of the main display panel MDP and the first side SS3-1 of the third sub-display panel SDP3. The length of the third side SS1-3 of the first sub-display panel SDP1 may be substantially equal to the sum of the length of the first side S1 of the main display panel MDP and the length of the first side SS3-1 of the third sub-display panel SDP3. The length of the fourth side SS1-4 of the first sub-display panel SDP1 may be substantially equal to the length of the third side SS1-3 of the first sub-display panel SDP1.

The first side SS2-1 of the second sub-display panel SDP2 may be in contact with the third side SS3-3 of the third sub-display panel SDP3, and the third side SS2-3 of the second sub-display panel SDP2 may be in contact with the second side S2 of the main display panel MDP and the first side SS4-1 of the fourth sub-display panel SDP4. The length of the third side SS2-3 of the second sub-display panel SDP2 may be substantially equal to the sum of the length of the second side S2 of the main display panel MDP and the length of the first side SS4-1 of the fourth sub-display panel SDP4. The length of the fourth side SS2-4 of the second sub-display panel SDP2 may be substantially equal to the length of the third side SS2-3 of the second sub-display panel SDP2.

The first side SS3-1 of the third sub-display panel SDP3 may be in contact with the third side SS1-3 of the first sub-display panel SDP1, and the third side SS3-3 of the third sub-display panel SDP3 may be in contact with the third side S3 of the main display panel MDP and the first side SS2-1 of the second sub-display panel SDP2. The length of the third side SS3-3 of the third sub-display panel SDP3 may be substantially equal to the sum of the length of the third side S3 of the main display panel MDP and the length of the first side SS2-1 of the second sub-display panel SDP2. The length of the fourth side SS3-4 of the third sub-display panel SDP3 may be substantially equal to the length of the third side SS3-3 of the third sub-display panel SDP3.

The first side SS4-1 of the fourth sub-display panel SDP4 may be in contact with the third side SS2-3 of the second sub-display panel SDP2, and the third side SS4-3 of the fourth sub-display panel SDP4 may be in contact with the fourth side S4 of the main display panel MDP and the first side SS1-1 of the first sub-display panel SDP1. The length of the third side SS4-3 of the fourth sub-display panel SDP4 may be substantially equal to the sum of the length of the fourth side S4 of the main display panel MDP and the length of the first side SS1-1 of the first sub-display panel SDP1. The length of the fourth side SS4-4 of the fourth sub-display panel SDP4 may be substantially equal to the length of the third side SS4-3 of the fourth sub-display panel SDP4.

The first sub-display panel SDP1 may include a display area SDA1 and a non-display area SNDA1. Multiple pixels PX1 may be arranged in the display area SDA1 of the first sub-display panel SDP1. The pixels PX1 may include pixels PX1 that provide light of different colors. For example, three pixels PX1 adjacent to one another in a direction (e.g., the first direction DR1) in the display area SDA1 of the first sub-display panel SDP1 may define a first pixel, a second pixel, and a third pixel, respectively. The first pixel among the three pixels PX1 may provide red light, the second pixel among the three pixels PX1 may provide green light, and the third pixel among the three pixels PX1 may provide blue light. Among the pixels PX1 of the first sub-display panel SDP1, a first pixel, a second pixel and a third pixel, which are arranged adjacent to each other, may form a unit pixel that displays a single unit image.

The first sub-circuit board SCB1 may be connected to the non-display area SNDA1 of the first sub-display panel SDP1. For example, a side of the first sub-circuit board SCB1 may electrically connect to pads arranged in the non-display area SNDA1 of the first sub-display panel SDP1 via a conductive adhesive member. The first sub-circuit board SCB1 may be connected to the first sub-display panel SDP1 to overlap the fourth side SS1-4 of the first sub-display panel SDP1. The first sub-circuit board SCB1 may extend along the fourth side SS1-4 of the first sub-display panel SDP1. For example, the first sub-circuit board SCB1 may extend along and overlap the fourth side SS1-4 of the two longer sides of the first sub-display panel SDP1 that is positioned furthest from the first side S1 of the main display panel MDP.

The first sub-driver circuit SDC1 may be located on the first sub-circuit board SCB1. The first sub-driver circuit SDC1 may provide power signals and driving signals required for driving the pixels PX1 of the first sub-display panel SDP1 (e.g., a scan signal and a data voltage). The driving signals and the power signals from the first sub-driver circuit SDC1 may be provided to the pixels PX1 of the first sub-display panel SDP1 through the transmission lines of the first sub-circuit board SCB1 and the pads of the first sub-display panel SDP1.

The second sub-display panel SDP2 may include a display area SDA2 and a non-display area SNDA2. Multiple pixels PX2 may be arranged in the display area SDA2 of the second sub-display panel SDP2. The pixels PX2 may include pixels PX2 that provide light of different colors. For example, three pixels PX2 adjacent to one another in a direction (e.g., the first direction DR1) in the display area SDA2 of the second sub-display panel SDP2 may define a first pixel, a second pixel, and a third pixel, respectively. The first pixel among the three pixels PX2 may provide red light, the second pixel among the three pixels PX2 may provide green light, and the third pixel among the three pixels PX2 may provide blue light. Among the pixels PX2 of the second sub-display panel SDP2, a first pixel, a second pixel and a third pixel, which are arranged adjacent to each other, may form a unit pixel that displays a single unit image.

The second sub-circuit board SCB2 may be connected to the non-display area SNDA2 of the second sub-display panel SDP2. For example, a side of the second sub-circuit board SCB2 may electrically connect to pads arranged in the non-display area SNDA2 of the second sub-display panel SDP2 via a conductive adhesive member. The second sub-circuit board SCB2 may be connected to the second sub-display panel SDP2 to overlap the fourth side SS2-4 of the second sub-display panel SDP2. The second sub-circuit board SCB2 may extend along the fourth side SS2-4 of the second sub-display panel SDP2. For example, the second sub-circuit board SCB2 may overlap the fourth side SS2-4 of the two longer sides of the second sub-display panel SDP2 that is positioned furthest from the second side S2 of the main display panel MDP and may extend along the fourth side SS2-4.

The second sub-driver circuit SDC2 may be located on the second sub-circuit board SCB2. The second sub-driver circuit SDC2 may provide power signals and driving signals required for driving the pixels PX2 of the second sub-display panel SDP2 (e.g., a scan signal and a data voltage). The driving signals and the power signals from the second sub-driver circuit SDC2 may be provided to the pixels PX2 of the second sub-display panel SDP2 through the transmission lines of the second sub-circuit board SCB2 and the pads of the second sub-display panel SDP2.

The third sub-display panel SDP3 may include a display area SDA3 and a non-display area SNDA3. Multiple pixels PX3 may be arranged in the display area SDA3 of the third sub-display panel SDP3. The pixels PX3 may include pixels PX3 that provide light of different colors. For example, three pixels PX3 adjacent to one another in a direction (e.g., the first direction DR1) in the display area SDA3 of the third sub-display panel SDP3 may define a first pixel, a second pixel, and a third pixel, respectively. The first pixel among the three pixels PX3 may provide red light, the second pixel among the three pixels PX3 may provide green light, and the third pixel among the three pixels PX3 may provide blue light. Among the pixels PX3 of the third sub-display panel SDP3, a first pixel, a second pixel and a third pixel, which are arranged adjacent to each other, may form a unit pixel that displays a single unit image.

The third sub-circuit board SCB3 may be connected to the non-display area SNDA3 of the third sub-display panel SDP3. For example, a side of the third sub-circuit board SCB3 may electrically connect to pads arranged in the non-display area SNDA3 of the third sub-display panel SDP3 via a conductive adhesive member. The third sub-circuit board SCB3 may be connected to the third sub-display panel SDP3 to overlap the fourth side SS3-4 of the third sub-display panel SDP3. The third sub-circuit board SCB3 may extend along the fourth side SS3-4 of the third sub-display panel SDP3. For example, the third sub-circuit board SCB3 may overlap the fourth side SS3-4 of the two longer sides of the third sub-display panel SDP3 that is positioned furthest from the third side S3 of the main display panel MDP and may extend along the fourth side SS3-4.

The third sub-driver circuit SDC3 may be located on the third sub-circuit board SCB3. The third sub-driver circuit SDC3 may provide power signals and driving signals required for driving the pixels PX3 of the third sub-display panel SDP3 (e.g., a scan signal and a data voltage). The driving signals and the power signals from the third sub-driver circuit SDC3 may be provided to the pixels PX3 of the third sub-display panel SDP3 through the transmission lines of the third sub-circuit board SCB3 and the pads of the third sub-display panel SDP3.

The fourth sub-display panel SDP4 may include a display area SDA4 and a non-display area SNDA4. Multiple pixels PX4 may be arranged in the display area SDA4 of the fourth sub-display panel SDP4. The pixels PX4 may provide light of different colors. For example, three pixels PX4 adjacent to one another in a direction (e.g., the first direction DR1) in the display area SDA4 of the fourth sub-display panel SDP4 may define a first pixel, a second pixel, and a third pixel, respectively. The first pixel among the three pixels PX4 may provide red light, the second pixel among the three pixels PX4 may provide green light, and the third pixel among the three pixels PX4 may provide blue light. Among the pixels PX4 of the fourth sub-display panel SDP4, a first pixel, a second pixel and a third pixel, which are arranged adjacent to each other, may form a unit pixel that displays a single unit image.

The fourth sub-circuit board SCB4 may be connected to the non-display area SNDA4 of the fourth sub-display panel SDP4. For example, a side of the fourth sub-circuit board SCB4 may electrically connect to pads arranged in the non-display area SNDA4 of the fourth sub-display panel SDP4 via a conductive adhesive member. The fourth sub-circuit board SCB4 may be connected to the fourth sub-display panel SDP4 to overlap the fourth side SS4-4 of the fourth sub-display panel SDP4. The fourth sub-circuit board SCB4 may extend along the fourth side SS4-4 of the fourth sub-display panel SDP4. For example, the fourth sub-circuit board SCB4 may overlap the fourth side SS4-4 of the two longer sides of the fourth sub-display panel SDP4 that is positioned furthest from the fourth side S4 of the main display panel MDP and may extend along the fourth side SS4-4.

The fourth sub-driver circuit SDC4 may be located on the fourth sub-circuit board SCB4. The fourth sub-driver circuit SDC4 may provide power signals and driving signals required for driving the pixels PX4 of the fourth sub-display panel SDP4 (e.g., a scan signal and a data voltage). The driving signals and the power signals from the fourth sub-driver circuit SDC4 may be provided to the pixels PX4 of the fourth sub-display panel SDP4 through the transmission lines of the fourth sub-circuit board SCB4 and the pads of the fourth sub-display panel SDP4.

The common circuit board CCB may be arranged on the lower surface of the main display panel MDP. The common circuit board CCB may electrically connect to the main circuit board MCB, the first sub-circuit board SCB1, the second sub-circuit board SCB2, the third sub-circuit board SCB3, and the fourth sub-circuit board SCB4. For example, the common circuit board CCB and the main circuit board MCB may electrically connect to each other via the main cable MCA, the common circuit board CCB and the first sub-circuit board SCB1 may electrically connect to each other via the first sub-cable SCA1, the common circuit board CCB and the second sub-circuit board SCB2 may electrically connect to each other via the second sub-cable SCA2, the common circuit board CCB and the third sub-circuit board SCB3 may electrically connect to each other via the third sub-cable SCA3, and the common circuit board CCB and the fourth sub-circuit board SCB4 may electrically connect to each other via the fourth sub-cable SCA4. The cables MCA, SCA1, SCA2, SCA3 and SCA4 may be connected to the cables of the common circuit board CCB and the connectors CTa and CTb of the circuit boards.

A timing controller TC and a power supply PS may be arranged on the common circuit board CCB. The timing controller TC may provide a scan control signal, a timing control signal, a data signal, etc., and the power supply PS may provide power signals. Scan control signals, timing control signals, and data signals from the timing controller TC and power signals from the power supply PS may be provided to the main driver circuit MDC through the common circuit board CCB, the main cable MCA, and the main circuit board MCB. The scan control signals, the timing control signals and the data signals from the timing controller TC and the power signals from the power supply PS may be provided to the first sub-driver circuit SCD1 through the common circuit board CCB, the first sub-cable SCA1, and the first sub-circuit board SCB1. The scan control signals, the timing control signals and the data signals from the timing controller TC and the power signals from the power supply PS may be provided to the second sub-driver circuit SCD2 through the common circuit board CCB, the second sub-cable SCA2, and the second sub-circuit board SCB2. The scan control signals, the timing control signals and the data signals from the timing controller TC and the power signals from the power supply PS may be provided to the third sub-driver circuit SCD3 through the common circuit board CCB, the third sub-cable SCA3, and the third sub-circuit board SCB3. The scan control signals, the timing control signals and the data signals from the timing controller TC and the power signals from the power supply PS may be provided to the fourth sub-driver circuit SCD4 through the common circuit board CCB, the fourth sub-cable SCA4, and the fourth sub-circuit board SCB4.

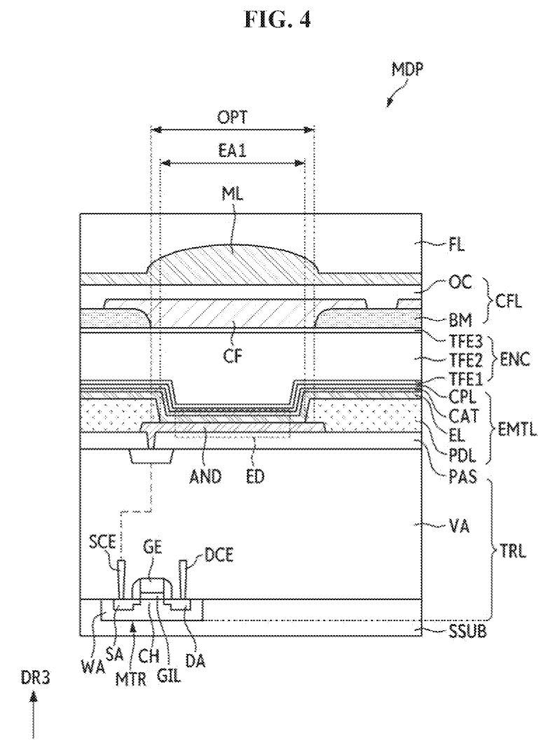

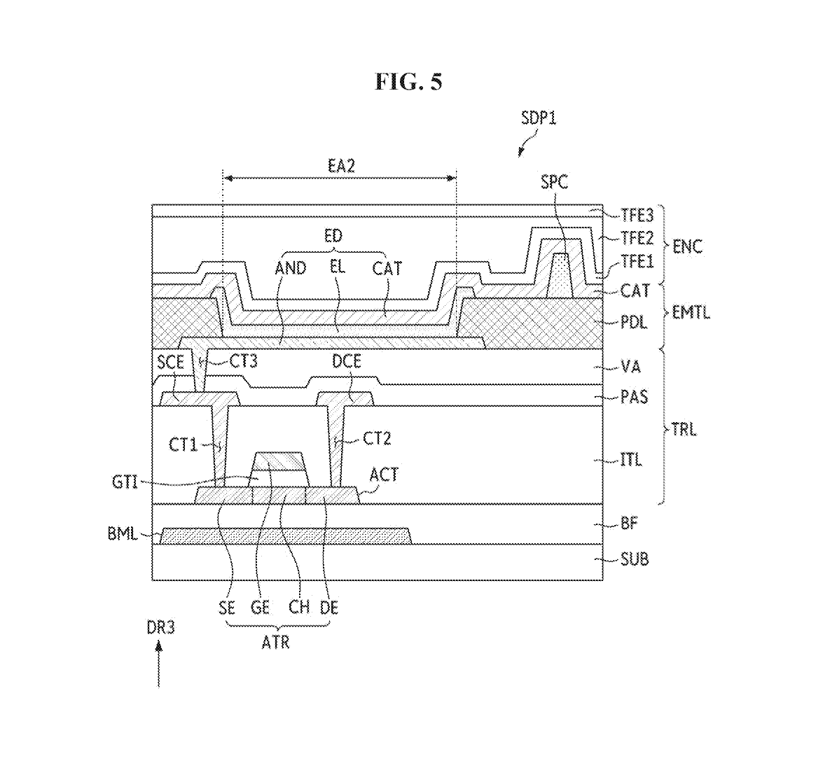

The pixel PX of the main display panel MDP and the pixel of the sub-display panel may have different areas. For example, the area of the pixel PX of the main display panel MDP may be smaller than the area of the pixel PX1 of the first sub-display panel SDP1. The areas of the pixels PX1 to PX4 of the sub-display panels SDP1 to SDP4 may all be substantially equal. For example, the pixels PX1 of the first sub-display panel SDP1, the pixels PX2 of the second sub-display panel SDP2, the pixels PX3 of the third sub-display panel SDP3, and the pixels PX4 of the fourth sub-display panel SDP4 may have the same area. As used herein, the area of a pixel may refer to, for example, the size of the emission area of that pixel. For example, the emission area of a pixel PX included in the main display panel MDP (e.g., the emission area EA1 of FIG. 4) may be smaller than the emission area of a pixel PX1 included in the first sub-display panel SDP1 (e.g., the emission area EA2 of FIG. 5).

According to the embodiment, the sub-circuit boards connected to adjacent sub-display panels may extend in different directions. Accordingly, it is possible to prevent interference and collision between the adjacent sub-circuit boards. For example, while the first sub-circuit board SCB1 extends in the second direction DR2, the fourth sub-circuit board SCB4 adjacent to the first sub-circuit board SCB1 extends in the first direction DR1, and thus interference and collision between the first sub-circuit board SCB1 and the fourth sub-circuit board SCB4 can be prevented.

According to an embodiment, the number of the transistors included in a pixel PX of the main display panel MDP may be different from the number of the transistors included in a sub-display panel. For example, the number of transistors included in a pixel PX of the main display panel MDP may be smaller than the number of transistors included in a pixel PX1 of the first sub-display panel SDP1.

According to an embodiment, the numbers of the transistors included in a pixel of each sub-display panel may all be substantially equal. For example, the number of transistors included in a pixel PX1 of the first sub-display panel SDP1, the number of transistors included in a pixel PX2 of the second sub-display panel SDP2, the number of transistors included in a pixel PX3 of the third sub-display panel SDP3, and the number of transistors included in a pixel PX4 of the fourth sub-display panel SDP4 may all be substantially equal.

FIG. 4 is a cross-sectional view of the main display panel MDP of FIG. 1.

The main display panel MDP may include a substrate SSUB (e.g., a semiconductor substrate or a wafer), a transistor layer TRL, an emission material layer EMTL, an encapsulation layer ENC, a color filter layer CFL, a lens (e.g., a micro lens), and a filling layer FL, as shown in FIG. 4.

The substrate SSUB may be a silicon substrate, a germanium substrate, or a silicon-germanium substrate. The substrate SSUB may be a substrate doped with first-type impurities.

A well region WA may be located in the substrate SSUB. The well region WA may be doped with second-type impurities. The second-type impurities may be different from the first-type impurities. For example, when the first-type impurities are p-type impurities, the second-type impurities may be n-type impurities. On the other hand, when the first-type impurities are n-type impurities, the second-type impurities may be p-type impurities.

A source region SA, a drain region DA and a channel region CH of a transistor MTR may be located in the well region WA. For example, the source region SA (or source electrode) and the drain region DA (or drain electrode) of the transistor TR may be located in the well region WA. Each of the source region SA and the drain region DA may be doped with the first-type impurities described above. The gate electrode GE of the transistor TR may cross and overlap the well region WA. When viewed from the top, portions of the well region WA disposed on opposing sides of the gate electrode GE in a plan view may define two regions. One of the two regions may be the source region SA while another may be the drain region DA In other words, in the well region WA, the source region SA and the drain region DA may be located on the opposite sides of the gate electrode GE, respectively, with the gate electrode GE being disposed between the source region SA and the drain region DA in a plan view. The channel region CH of the transistor MTR may be a portion of the well region WA that overlaps the gate electrode GE in a plan view. The transistor MTR may be, for example, a metal-oxide-semiconductor (MOS) transistor.

The drain region DA of the transistor MTR may be connected to a drain connection electrode DCE.

A gate insulator GIL may be disposed between the channel region CH and the gate electrode GE.

An interlayer dielectric layer VA may be disposed on the substrate SSUB.

A passivation layer PAS may be disposed on the interlayer dielectric layer VA.

The emission material layer EMTL may be disposed on the passivation layer PAS. The emission material layer EMTL may include a light-emitting element ED. For example, the light-emitting element ED in the emission material layer EMTL may be located in a first emission area EA1.

The light-emitting element ED may include a first electrode AND (e.g., an anode electrode), an emissive layer EL, and a second electrode CAT that are stacked on each other in the third direction DR3.

The first electrode AND may be connected to a source region SD of a transistor MTR via a source connection electrode SCE.

The first electrode AND may be arranged in the first emission area EA1.

A pixel-defining layer PDL may be disposed over the first electrode AND.

The pixel-defining layer PDL may define the first emission area EA of a pixel. To this end, the pixel-defining layer PDL may be formed on the passivation layer PAS to expose a part of the first electrode AND. The pixel-defining layer PDL may cover an edge of the first electrode AND.

The emissive layer EL may be arranged over the first electrode AND and the pixel-defining layer PDL. The emissive layer EL may emit light.

The second electrode CAT may be disposed on the emissive layer EL. For example, the second electrode CAT may be disposed on the emissive layer EL such that it overlaps the first electrode AND, the emission area EA1 and the pixel-defining layer PDL.

A capping layer CPL may be disposed on the second electrode CAT. The capping layer CPL may include an inorganic insulating material.

An encapsulation layer ENC may be disposed on the capping layer CPL. The encapsulation layer ENC may cover the upper and side surfaces of the emission material layer EMTL, and can protect the emission material layer EMTL. The encapsulation layer ENC may include a first inorganic encapsulation layer TFE1, an organic encapsulation layer TFE2 and a second inorganic encapsulation layer TFE3.

The first inorganic encapsulation layer TFE1 may be disposed on the capping layer CPL, the organic encapsulation layer TFE2 may be disposed on the first inorganic encapsulation layer TFE1, and the second inorganic encapsulation layer TFE3 may be disposed on the organic encapsulation layer TFE2. The first inorganic encapsulation layer TFE1 and the second inorganic encapsulation layer TFE3 may be made up of multiple layers in which one or more inorganic layers of a silicon nitride layer, a silicon oxynitride layer, a silicon oxide layer, a titanium oxide layer and an aluminum oxide layer are alternately stacked on each other. The organic encapsulation layer TFE2 may be an organic layer such as an acryl resin, an epoxy resin, a phenolic resin, a polyamide resin, a polyimide resin, or a combination thereof.

A light-blocking layer BM may be disposed on the encapsulation layer ENC. The light-blocking layer BM may include a hole OPT that overlaps the emission area EA1 in a plan view. The area or size of the hole OPT may be larger than the area or size of the emission area EA1 defined by the pixel-defining layer PDL. As the hole OPT of the light-blocking layer BM is larger than the emission area EA1, the light output from the emission area EA1 may be seen by the user not only from the front but also from the sides of the display device 10.

The display device 10 may include a color filter CF disposed on the emission area EA1. The color filter CF may overlap the emission area EA1 in a plan view. For example, the color filter CF may overlap the hole OPT of the light-blocking layer BM and overlap the emission area EA1 in a plan view.

The overcoat layer OC may be arranged over adjacent color filters CF to provide a substantially flat surface over the color filters CF. The overcoat layer OC may be a colorless light-transmitting layer having no color in the visible light range. For example, the overcoat layer OC may include a colorless light-transmitting organic material such as an acryl resin.

A lens ML may be disposed on the overcoat layer OC. The lens ML may overlap the emission area EA1 or the hole OPT.

The lens ML may have a larger size than the hole OPT. For example, the lens ML may completely cover the holes OPT and partially overlap the light-blocking layer BM.

The filling layer FL may be disposed on the lens ML. The filling layer FL may be arranged between adjacent lenses ML.

FIG. 5 is a cross-sectional view of the first sub-display panel SDP1 of FIG. 1.

As shown in FIG. 5, the first sub-display panel SDP1 may include the substrate SUB, the light-blocking layer BML, the buffer layer BF, the transistor layer TRL, the emission material layer EMTL, and the encapsulation layer ENC. The light-blocking layer BML, the buffer layer BF, the transistor layer TRL, the emission material layer EMTL and the encapsulation layer ENC may be sequentially arranged on the substrate SUB in the third direction DR3.

The substrate SUB may be a rigid substrate or a flexible substrate that can be bent, folded, rolled, and so on. The substrate SUB may be made of an insulating material such as glass, quartz and a polymer resin. For example, the substrate SUB may include a metallic material.

The light-blocking layer BML may be disposed on the substrate SUB. The light-blocking layer BML may be arranged on the substrate SUB to overlap an active layer ACT to be described later. The light-blocking layer BML may be formed of, for example, a metal material such as chromium (Cr) and molybdenum (Mo), or black ink or black dye.

The buffer layer BF may be disposed on the light-blocking layer BML. The buffer layer BF may be located on the entire surface of the substrate SUB including the light-blocking layer BML. The buffer layer BF can protect a transistor ATR of the transistor layer TRL and an emissive layer EL of the emission material layer EMTL from the moisture permeating through the substrate SUB that is vulnerable to moisture permeation.

The active layer ACT may be arranged on the buffer layer BF. The first active layer ACT1 may be, for example, oxide semiconductor. For example, the first active layer ACT1 may be semiconductor that includes indium-gallium-zinc-oxide (IGZO) or indium-gallium-zinc-tin oxide (IGZTO).

A gate insulator GTI may be located on the active layer ACT. For example, the gate insulator GTI may overlap the channel region CH of the active layer ACT.

The gate electrode GE may be arranged on the gate insulator GTI. The gate electrode GE may be arranged on the gate insulator GTI to overlap the channel region CH of the active layer ACT.

An interlayer dielectric layer ITL may be arranged on the gate electrode GE. The interlayer dielectric layer ITL may be arranged on the entire surface of the substrate SUB including the gate electrode GE in a plan view or when viewed from above in a thickness direction of the display device.

The source connection electrode SCE and the drain connection electrode DCE may be arranged on the interlayer dielectric layer ITL. The source connection electrode SCE may be connected to the source electrode SE of the active layer ACT through a first contact hole CT1 penetrating the interlayer dielectric layer ITL. The drain connection electrode DCE may be connected to the drain electrode DE of the active layer ACT through a second contact hole CT2 penetrating the interlayer dielectric layer ITL.

The passivation layer PAS may be arranged on the source connection electrode SCE and the drain connection electrode DCE. The passivation layer PAS may be arranged on the entire surface of the substrate SUB including the interlayer dielectric layer ITL.

A planarization layer VA may be disposed on the passivation layer PAS. The planarization layer VA may be disposed on the entire surface of the substrate SUB including the passivation layer PAS.

The emission material layer EMTL including the first electrode AND may be disposed on the planarization layer VA. The first electrode AND may be connected to the source connection electrode SCE through a third contact hole CT3 penetrating the planarization layer VA. The first electrode AND may be connected to the source electrode SE of the active layer ACT via the source connection electrode SCE.

The emission material layer EMTL may include the light-emitting element ED and the pixel-defining layer PDL. The light-emitting element ED may include the first electrode AND, the emissive layer EL, and the second electrode CAT sequentially stacked on each other.

The light-emitting element ED may include a first electrode AND, an emissive layer EL, and a second electrode CAT. In the emission area EA2, the first electrode AND, the emissive layer EL and the second electrode CAT may be sequentially stacked on each other so that holes from the first electrode AND and electrons from the second electrode CAT may be combined with each other in the emissive layer EL to emit light. In this instance, the first electrode AND may be an anode electrode of the light-emitting element ED and the second electrode CAT may be a cathode electrode of the light-emitting element ED.

The pixel-defining layer PDL defines the emission area EA2 of the first pixel. To this end, the pixel-defining layer PDL may expose a part of the first electrode AND on the planarization layer VA. The pixel-defining layer PDL may cover an edge of the first electrode AND.

A spacer SPC may be disposed on the pixel-defining layer PDL. The spacer SPC may support a mask during a process of fabricating the emissive layer EL.

The emissive layer EL may be formed on the first electrode AND. The emissive layer EL may include an organic material to emit light of a certain color.

The second electrode CAT may be disposed on the emissive layer EL.

The encapsulation layer ENC may be formed on the emission material layer EMTL. The encapsulation layer ENC may include one or more inorganic layers TFE1 and TFE3 to prevent permeation of oxygen or moisture into the emission material layer EMTL. The encapsulation layer ENC may include at least one organic layer to protect the emission material layer EMTL from particles such as dust. For example, the encapsulation layer ENC may include a first inorganic encapsulation layer TFE1, an organic encapsulation layer TFE2 and a second inorganic encapsulation layer TFE3.

FIG. 6 is an equivalent circuit diagram of a pixel of a display device according to an embodiment. For example, FIG. 6 is an equivalent circuit diagram of a pixel PX arranged in the main display panel MDP of FIG. 1 described above.

The pixel PX may be connected to a first gate line GWL, a second gate line EBL, an emission control line EML , a data line DL, a driving voltage line VDL, a common voltage line VSL, a reference voltage line VRL, and an initialization voltage line VIL.

The pixel PX may include a pixel circuit PC and a light-emitting element ED connected to the pixel circuit PC.

The pixel circuit PC may include a first transistor T1 (e.g., a driving transistor), a second transistor T2 (e.g., a switching transistor), a third transistor T3 (e.g., an emission control transistor), a fourth transistor T4 (e.g., an initialization transistor), a first capacitor C1, a second capacitor C2, and a third capacitor C3.

The first transistor T1 may control a source-drain current (e.g., driving current) according to a data voltage applied to the gate electrode. The driving current flowing through the channel region of the first transistor T1 may be proportional to the square of the difference between the threshold voltage and the voltage between the source electrode and the gate electrode of the first transistor T1. The first transistor T1 may include a gate electrode connected to a first node N1, a source electrode connected to a second node N2, a drain electrode connected to a third node N3, and a body electrode connected to the driving voltage line VDL.

The second transistor T2 may be turned on by a first gate signal GW of the first gate line GWL to electrically connect the data line DL to the first node N1. The second transistor T2 may be turned on based on the first gate signal GW, thereby providing a data voltage from the data line DL to the first node N1. The second transistor T2 may include a gate electrode connected to the first gate line GWL, a source electrode connected to the data line DL, a drain electrode connected to the first node N1, and a body electrode connected to the driving voltage line VDL.

The third transistor T3 may be turned on by an emission control signal EM from an emission control line EML to electrically connect the driving voltage line VDL to the second node N2. The third transistor T3 may be turned on based on the emission control signal EM to provide a supply voltage VD from the driving voltage line VDL to the second node N2. The third transistor T3 may include a gate electrode connected to the emission control line EML, a source electrode connected to the driving voltage line VDL, a drain electrode connected to the second node N2, and a body electrode connected to the driving voltage line VDL.

The fourth transistor T4 may be turned on by a second gate signal EB from the second gate line EBL to electrically connect the third node N3 to the initialization voltage line VIL. The fourth transistor T4 may be turned on based on the second gate signal EB, thereby providing an initialization voltage VINT from the initialization voltage line VIL to the third node N3. The fourth transistor T4 may include a gate electrode connected to the second gate line EBL, a source electrode connected to the third node N3, a drain electrode connected to the initialization voltage line VIL, and a body electrode connected to the driving voltage line VDL.

The first capacitor C1 may be connected between the first node N1 and the second node N2. For example, a first electrode of the first capacitor C1 may be connected to the first node N1, and a second electrode of the first capacitor C1 may be connected to the second node N2.

The second capacitor C2 may be connected between the first node N1 and the reference voltage line VRL. For example, a first electrode of the second capacitor C2 may be connected to the first node N1, and a second electrode of the second capacitor C2 may be connected to the reference voltage line VRL.

The third capacitor C3 may be connected between the first node N1 and the third node N3. For example, a first electrode of the third capacitor C3 may be connected to the first node N1, and a second electrode of the third capacitor C3 may be connected to the third node N3.

The light-emitting element ED may receive the driving current to emit light. The amount or the brightness of the light emitted from the light-emitting element ED may be proportional to the magnitude of the driving current.

The light-emitting element ED may be an organic light-emitting diode including a first electrode (e.g., a pixel electrode or an anode electrode), a second electrode (e.g., a common electrode or a cathode electrode), and an organic emissive layer disposed between the first electrode and the second electrode of the light-emitting element ED. For another example, the light-emitting element ED may be an inorganic light-emitting element including a first electrode, a second electrode, and an inorganic semiconductor disposed between the first electrode and the second electrode of that light-emitting element ED. For yet another example, the light-emitting element ED may be a quantum-dot light-emitting element including a first electrode, a second electrode, and a quantum-dot emissive layer disposed between the first electrode and the second electrode of that quantum-dot light-emitting element. As another example, the light-emitting element ED may be a micro light-emitting diode.

The first electrode of the light-emitting element ED may electrically connect to a third node N3. The first electrode of the light-emitting element ED may be connected to the drain electrode of the first transistor T1, the source electrode of the fourth transistor T4, and the second electrode of the third capacitor C3 through the third node N3. The second electrode of the light-emitting element ED may be connected to the common voltage line VSL. The second electrode of the light-emitting element ED may receive a common voltage VS (e.g., a low-level voltage) from the common voltage line VSL.

The driving transistor (e.g., the first transistor T1) of the pixel PX of FIG. 6 may be a source-follower transistor having its threshold voltage (e.g., the threshold voltage of the first transistor T1) compensated. For example, the source electrode of the first transistor T1 may be connected to the driving voltage line VDL through the third transistor T3, so that the threshold voltage of the first transistor T1 thus connected may be detected and compensated in a source-follower configuration.

FIG. 7 is an equivalent circuit diagram of a pixel of a display device according to an embodiment. For example, FIG. 7 is an equivalent circuit diagram of a pixel PX1 arranged in the first sub-display panel SDP1 of FIG. 1 described above.

The pixel PX1 may be connected to a first gate line GWL, a second gate line GCL, a third gate line GIL, a fourth gate line EBL, an emission control line EML, a data line DL, a driving voltage line VDL, a common voltage line VSL, a first initialization voltage line VIL1, a second initialization voltage line VIL2, and a bias voltage line VBL.

The pixel PX1 may include a pixel circuit PC’ and a light-emitting element ED connected to the pixel circuit PC’. The pixel circuit PC’ may include a first transistor T1, a second transistor T2, a third transistor T3, a fourth transistor T4, a fifth transistor T5, a sixth transistor T6, a seventh transistor T7, an eighth transistor T8, and a capacitor Cst.

The first transistor T1 may include a gate electrode, a source electrode, and a drain electrode. The first transistor T1 may control a source-drain current (e.g., driving current) according to a data voltage applied to the gate electrode. The driving current flowing through the channel region of the first transistor T1 may be proportional to the square of the difference between the threshold voltage and the voltage between the source electrode and the gate electrode of the first transistor T1.

The second transistor T2 may be turned on by a first gate signal GW of the first gate line GWL to electrically connect the data line DL to the first node N1, which is the source electrode of the first transistor T1. The second transistor T2 may be turned on in response to the first gate signal GW to apply data voltage to the first node N1. The second transistor T2 may include a gate electrode connected to the first gate line GWL, a source electrode connected to the data line DL, and a drain electrode connected to the first node N1.

The third transistor T3 may be turned on by a second gate signal GC of the second gate line GCL and may electrically connect a second node N2 which is the drain electrode of the first transistor T1 to a third node N3 which is the gate electrode of the first transistor T1. The third transistor T3 may be connected between the third node N3 and the second node N2. The third transistor T3 may include a gate electrode connected to the second gate line GCL, a source electrode connected to the third node N3, and a drain electrode connected to the second node N2. The third transistor T3 may be turned on by a second gate signal GC of the second gate line GCL and may electrically connect a second node N2 which is the drain electrode of the first transistor T1 to a third node N3 which is the gate electrode of the first transistor T1. The third transistor T3 may be a double-gate transistor having two gate electrodes (e.g., a gate electrode and a counter gate electrode). The gate electrode and the counter gate electrode may face each other on different layers.

The fourth transistor T4 may be turned on by a third gate signal GI of the third gate line GIL to electrically connect the third node N3 which is the gate electrode of the first transistor T1 to the first initialization voltage line VIL1. The fourth transistor T4 may be connected in series between the third node N3 and the first initialization voltage line VIL1. The fourth transistor T4 may include a gate electrode connected to the third gate line GIL, a source electrode connected to the third node N3, and a drain electrode connected to the first initialization voltage line VIL1. The fourth transistor T4 may be a double-gate transistor. The first initialization voltage line VIL1 may transmit a first initialization voltage VI1.

The fifth transistor T5 may be turned on by an emission control signal EM of the emission control line EML and may electrically connect the first driving voltage line VD to the first node N1 that is the source electrode of the first transistor T1. The fifth transistor T5 may include a gate electrode connected to the emission control line EML, a source electrode connected to the driving voltage line VDL, and a drain electrode connected to the first node N1.

The sixth transistor T6 may be turned on by the emission control signal EM of the emission control line EML to electrically connect the second node N2 which is the drain electrode of the first transistor T1 to the fourth node N4 which is the first electrode of the light-emitting element ED. The sixth transistor T6 may include a gate electrode connected to the emission control line EML, a source electrode connected to the second node N2, and a drain electrode connected to the fourth node N4.

When all of the fifth transistor T5, the first transistor T1 and the sixth transistor T6 are turned on, the driving current may be supplied to the light-emitting element ED.

The seventh transistor T7 may be turned on by a fourth gate signal EB of the fourth gate line EBL to electrically connect the fourth node N4 which is the first electrode of the light-emitting element ED to the second initialization voltage line VIL2. As the seventh transistor T7 is turned on based on the fourth gate signal EB, the first electrode of the light-emitting element ED may be discharged to a second initialization voltage VI2. The seventh transistor T7 may include a gate electrode connected to the fourth gate line EBL, a source electrode connected to the fourth node N4, and a drain electrode connected to the second initialization voltage line VIL2. The second initialization voltage line VIL2 may transmit a second initialization voltage VI2.

The eighth transistor T8 may be turned on by the fourth gate signal EB of the fourth gate line EBL to electrically connect the bias voltage line VBL to the first node N1 which is the source electrode of the first transistor T1. The eighth transistor T8 may be turned on based on the fourth gate signal EB to apply the bias voltage VB to the first node N1. The eighth transistor T8 can improve hysteresis of the first transistor T1 by applying the bias voltage VB to the source electrode of the first transistor T1. The eighth transistor T8 may include a gate electrode connected to the fourth gate line EBL, a source electrode connected to the bias voltage line VBL, and a drain electrode electrically connected to the first node N1.

Each of the first transistor T1, the second transistor T2, the fifth transistor T5, the sixth transistor T6, the seventh transistor T7 and the eighth transistor T8 may include a silicon-based active layer. For example, each of the first transistor T1, the second transistor T2, the fifth transistor T5, the sixth transistor T6, the seventh transistor T7 and the eighth transistor T8 may be a p-type transistor including an active layer made of low-temperature polycrystalline silicon (LTPS). The active layer made of low-temperature polycrystalline silicon may have a high electron mobility and excellent turn-on characteristics. Accordingly, as the display device 10 includes transistors having excellent turn-on characteristics, the pixels PX1 can be driven stably and efficiently. Each of the first transistor T1, the second transistor T2, the fifth transistor T5, the sixth transistor T6, the seventh transistor T7 and the eighth transistor T8 may output the current introduced from the source electrode via the drain electrode based on a gate-low voltage applied to the gate electrode.

The third transistor T3 and the fourth transistor T4 may be n-type transistors including an oxide-based active layer. A transistor including an oxide-based active layer may have a coplanar structure in which a gate electrode is disposed at the top. A transistor including an oxide-based active layer may output current introduced into the drain electrode via the source electrode based on a gate-high voltage applied to the gate electrode.

The capacitor Cst may electrically connect between the third node N3 which is the gate electrode of the first transistor T1 and the driving voltage line VDL. For example, the first electrode of the capacitor Cst may electrically connect to the third node N3 and the second electrode of the capacitor Cst may electrically connect to the driving voltage line VDL, so that a potential difference between the driving voltage line VDL and the gate electrode of the first transistor T1 can be maintained.

The first electrode of the light-emitting element ED may electrically connect to a fourth node N4. The first electrode of the light-emitting element ED may be connected to the drain electrode of the sixth transistor T6 and the source electrode of the seventh transistor T7 through the fourth node N4. The second electrode of the light-emitting element ED may be connected to the common voltage line VSL. The second electrode of the light-emitting element ED may receive a second driving voltage VS (e.g., a low-level voltage) from the common voltage line VSL.

The driving transistor (e.g., the first transistor T1) of the pixel PX1 of FIG. 7 may be a diode-connected transistor having its threshold voltage (e.g., the threshold voltage of the first transistor T1) compensated. For example, the third transistor T3 is connected between the gate electrode and the drain electrode of the first transistor T1, and thus the threshold voltage of the first transistor T1 thus connected may be detected and compensated in a diode-connected configuration.

The second pixel PX2 arranged on the second sub-display panel SDP2, the third pixel PX3 arranged on the third sub-display panel SDP3, and the fourth pixel PX4 arranged on the fourth sub-display panel SDP4 may have the same configuration as the pixel PX1 of FIG. 7.

According to the embodiment, a pixel (e.g., pixel PX1) of a sub-display panel (e.g., a first sub-display panel SDP1) has a larger size than the pixel PX of the main display panel MDP. Accordingly, the resolution of a sub-display panel (e.g., the sub-display panel SDP1) may be lower than the resolution of the main display panel MDP.

According to an embodiment, the number of transistors T1 to T8 provided in the pixel circuit PC’ of the sub-display panel (e.g., SDP1) having a relatively low resolution may be greater than the number of transistors T1 to T4 provided in the pixel circuit PC of the main display panel MDP having a relatively high resolution.

FIG. 8 is a view for illustrating the effects achieved by the display device according to the embodiment.

In the table shown in FIG. 8, an image of 11G (i.e., 11 grayscale levels) was used as an example. Deviations (or dispersions) of the luminance uniformity (e.g., short-range uniformity (SRU)) of the main display panel including the source-follower driving transistors on a wafer substrate may be approximately 12.2%, deviations of the luminance uniformity of the sub-display panel including the diode-connected driving transistors on a glass substrate (e.g., the first sub-display panel SDP1) may be approximately 26.8%, and deviations of the luminance uniformity of the sub-display panel including the source-follower driving transistors on a glass substrate (e.g., the first sub-display panel SDP1) may be approximately 46.5%.

It can be seen from FIG. 8 that the deviations in luminance uniformity is not large when the source-follower pixel circuit is formed on the wafer-based substrate, whereas the deviations in luminance uniformity is considerably large when the source-follower pixel circuit is formed on the glass-based substrate. It should be noted that the deviations in luminance uniformity can be improved when the diode-connected pixel circuit is formed on the glass-based substrate. Therefore, as in the embodiment where the source-follower pixel circuit is formed on the main display panel including a wafer-based substrate while the diode-connected pixel circuit is formed on the sub-display panel including a glass-based substrate, the difference between the luminance uniformity deviations of the main display panel and the luminance uniformity deviations of the sub-display panel is reduced to 14.6% (26.8% - 12.2%), so that the image quality of the display device can be significantly improved. In other words, according to the embodiment, the deviations in luminance between the main display panel and the sub-display panel having different resolutions can be reduced, thereby improving the image quality of the display device.

According to embodiments of the disclosure, the pixel circuits PC of the main display panel MDP and the pixel circuits PC’ of the sub-display panels SDP1, SDP2, SDP3, and SDP4 may be designed differently to reduce a difference in luminance uniformity deviations between the main display panel and the sub-display panels. Although this results in the resolution of the sub-display panels being lower than in the main display panel, image quality of the overall display device and the electronic device that includes the same is improved.

Since the diode-connected pixel circuit PC’ inherently includes a larger number of transistors than the source-follower pixel circuit PC, the pixel PX1 of the sub-display panel SDP1 including the diode-connected pixel circuit PC’ has a larger size than the pixel PX of the main display panel MDP including the source-follower pixel circuit PC as described above, and accordingly a large number of transistors can be sufficiently integrated into the pixel PX1 of the sub-display panel SDP1.

The display device 10 according to the embodiment may be applied to a variety of electronic devices. An electronic device according to an embodiment includes the display device 10 described above, and may further include a module or device having additional features in addition to the display device 10.

FIG. 9 is a block diagram of an electronic device according to an embodiment of the disclosure. Referring to FIG. 9, an electronic device 50 according to an embodiment of the disclosure may include a display module 11, a processor 12, a memory 13, and a power module 14. The electronic device 50 may further include an input module 15, a non-image output module 16, and/or a communication module 17.

The electronic device 50 may output various information in the form of images through the display module 11. When the processor 12 executes an application stored in the memory 13, image information provided by the application may be provided to the user through the display module 11. The power module 14 may include a power supply module such as a power adapter and a battery device, and a power conversion module that converts the power supplied by the power supply module 14 to generate power required for the operation of the electronic device 50. The input module 15 may provide input information to the processor 12 and/or the display module 11. The non-image output module 16 may receive information other than images from the processor 12, such as sound, haptic and light information, and provide it to the user. The communication module 17 may be responsible for transmitting and receiving information between the electronic device 50 and an external device, and may include a receiving unit and a transmitting unit.

At least one of the elements of the electronic device 50 described above may be included in the display devices according to the embodiments described above. Some of the individual modules functioning as a single module may be included in the display device while some others may be provided separately from the display device. For example, the display device may include the display module 11 while the processor 12, the memory 13 and the power module 14 may be implemented as other devices inside the electronic device 11 instead of the display device.

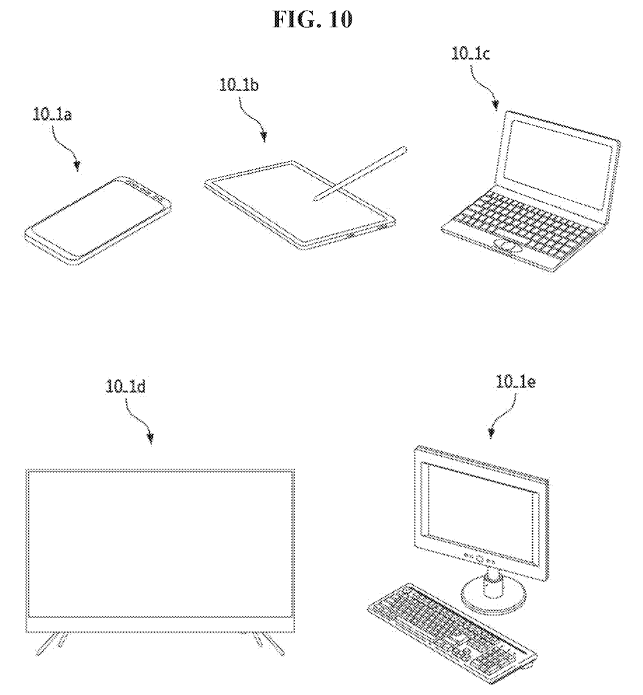

FIGS. 10, 11 and 12 are views showing electronic devices according to a variety of embodiments of the disclosure. FIGS. 10 - 12 show examples of a variety of electronic devices employing the display devices 10 according to the embodiments.

FIG. 10 shows a smartphone 10_1a, a tablet 10_1b, a laptop computer 10_1c, a TV 10_1d, and a monitor 10_1e as examples of the electronic devices.

The smartphone 10_1a may include an input module such as a touch sensor and a communication module in addition to a display module 11. The smartphone 10_1a may process information received through the communication module or other input modules and display the information through the display module of the display device.

The tablet 10_1b, the laptop computer 10_1c, the TV 10_1d and the monitor 10_1e may include display modules and input modules similar to the smartphone 10_1a, and may further include communication modules as desired.

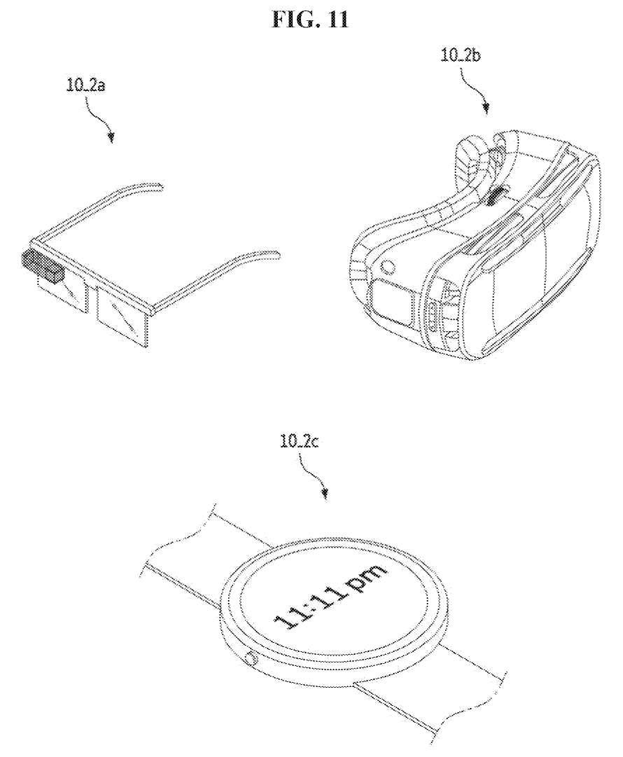

FIG. 11 shows examples of a wearable electronic device employing an electronic device including a display module. The wearable electronic devices may be smart glasses 10_2a, a head-mounted display 10_2b, a smart watch 10_2c, etc.

The smart glasses 10_2a and the head-mounted display 10_2b may include a display module that outputs display images, and a reflector that reflects the output display images and provides it to the user's eyes, thereby providing the user with images of virtual reality or augmented reality on the screen.

The smart watch 10_2c includes a biometric sensor as an input device, and may provide the user with biometric information recognized by the biometric sensor through the display module.

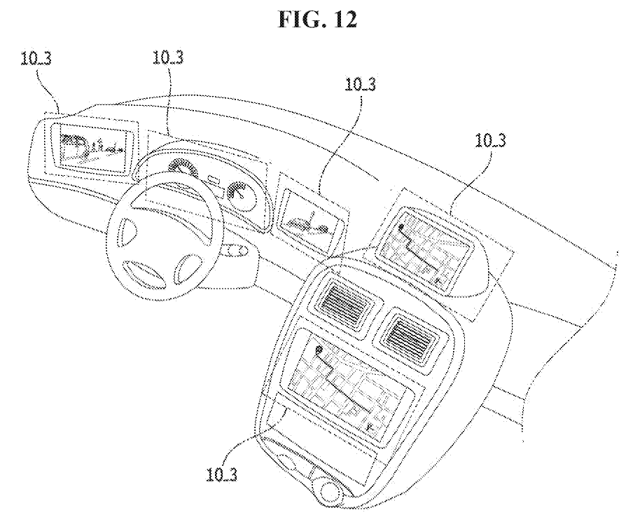

FIG. 12 shows an example of an electronic device including a display module applied to a vehicle. For example, an electronic device 10_3 may be applied to the instrument cluster, the center fascia, etc., of a vehicle, or may be applied to a center information display (CID) disposed at the dashboard of a vehicle, or may be used as a room mirror display on the behalf of the side mirrors of a vehicle.

In concluding the detailed description, those skilled in the art will appreciate that many variations and modifications can be made to the embodiments without substantially departing from the principles of the disclosure. Therefore, the disclosed embodiments of the disclosure are used in a generic and descriptive sense only and not for purposes of limitation.

What is claimed is:

1. A display device comprising:
a main display panel comprising a wafer-based substrate;
at least one sub-display panel comprising a glass-based substrate and adjacent to the main display panel;
a first pixel arranged in a display area of the main display panel, the first pixel includes a source-follower pixel circuit; and
a second pixel arranged in a display area of the sub-display panel, the second pixel includes a diode-connected pixel circuit, the second pixel having a size larger than the first pixel.

2. The display device of claim 1, wherein a number of transistors of the second pixel is greater than a number of transistors of the first pixel.

3. The display device of claim 2, wherein
the transistors of the first pixel comprise a first transistor which is a driving transistor of the first pixel, and
the transistors of the second pixel comprise a first transistor which is a driving transistor of the second pixel.

4. The display device of claim 3, wherein
the first transistor of the first pixel is connected to another transistor of the first pixel in a source-follower configuration, and
the first transistor of the second pixel is connected to another transistor of the second pixel in a diode-connected configuration.

5. The display device of claim 1, wherein the first pixel comprises:
a first transistor comprising a gate electrode connected to a first node, a source electrode connected to a second node, a drain electrode connected to a third node, and a body electrode connected to a driving voltage line;
a second transistor comprising a gate electrode connected to a first gate line, a source electrode connected to a data line, a drain electrode connected to the first node, and a body electrode connected to the driving voltage line;
a third transistor comprising a gate electrode connected to an emission control line, a source electrode connected to the driving voltage line, a drain electrode connected to the second node, and a body electrode connected to the driving voltage line;
a fourth transistor comprising a gate electrode connected to a second gate line, a source electrode connected to the third node, a drain electrode connected to an initialization voltage line, and a body electrode connected to the driving voltage line;
a first capacitor connected between the first node and the second node;
a second capacitor connected between the first node and a reference voltage line;
a third capacitor connected between the first node and the third node; and
a light-emitting element connected between the third node and a common voltage line.

6. The display device of claim 1, wherein the second pixel comprises:
a first transistor comprising a gate electrode connected to a third node, a source electrode connected to a first node, and a drain electrode connected to a second node;
a second transistor comprising a gate electrode connected to a first gate line, a source electrode connected to a data line, and a drain electrode connected to the first node;
a third transistor comprising a gate electrode connected to a second gate line, a source electrode connected to the third node, and a drain electrode connected to the second node;
a fourth transistor comprising a gate electrode connected to a third gate line, a source electrode connected to the third node, and a drain electrode connected to a first initialization voltage line;
a fifth transistor comprising a gate electrode connected to an emission control line, a source electrode connected to a driving voltage line, and a drain electrode connected to the first node;
a sixth transistor comprising a gate electrode connected to the emission control line, a source electrode connected to the second node, and a drain electrode connected to a fourth node;
a seventh transistor comprising a gate electrode connected to a fourth gate line, a source electrode connected to the fourth node, and a drain electrode connected to a second initialization voltage line;
an eighth transistor comprising a gate electrode connected to the fourth gate line, a source electrode connected to a bias voltage line, and a drain electrode connected to the first node;
a capacitor connected between the third node and the driving voltage line; and
a light-emitting element connected between the fourth node and a common voltage line.

7. The display device of claim 1, wherein the main display panel comprises:
a first side extended in a first direction; and
a second side adjacent to the first side and extended in a second direction intersecting an extension direction of the first side.

8. The display device of claim 7, wherein the at least one sub-display panel comprises a first sub-display panel and a second sub-display panel adjacent to the main display panel.

9. The display device of claim 8, wherein
the first sub-display panel is located on the first side of the main display panel and extends in the first direction, and
the second sub-display panel is located on the second side of the main display panel and extends in the second direction.

10. The display device of claim 9, further comprising:
a first sub-circuit board connected to the first sub-display panel to overlap a first side of the first sub-display panel; and
a second sub-circuit board connected to the second sub-display panel to overlap a first side of the second sub-display panel.

11. The display device of claim 10, wherein the first side of the first sub-display panel extends in the first direction, and the first side of the second sub-display panel extends in the second direction.

12. The display device of claim 11, wherein
a length of the first side of the first sub-display panel is substantially equal to a sum of a length of the first side of the main display panel and a length of a second side of the second sub-display panel, and
the second side of the second sub-display panel is adjacent to the first side of the second sub-display panel and extends in the first direction.

13. The display device of claim 11, wherein
a second side of the first sub-display panel faces the first side of the first sub-display panel, and
the second side of the first sub-display panel is in contact with the first side of the main display panel.

14. The display device of claim 13, wherein
a third side of the main display panel faces the second side of the main display panel,
a third side of the first sub-display panel is arranged in a same line as the third side of the main display panel,
an extension line of the second side of the main display panel is located between the third side of the first sub-display panel and a fourth side of the first sub-display panel to overlap the first sub-display panel, and
the fourth side of the first sub-display panel faces the third side of the first sub-display panel.

15. The display device of claim 11, wherein
a second side of the second sub-display panel faces the first side of the second sub-display panel, and
the second side of the second sub-display panel is in contact with the second side of the main display panel.

16. The display device of claim 15, wherein
a fourth side of the main display panel faces the first side of the main display panel,
a third side of the second sub-display panel is arranged in a same line as the first side of the main display panel,
an extension line of the fourth side of the main display panel is located between the third side of the second sub-display panel and a fourth side of the second sub-display panel to overlap the second sub-display panel, and
the fourth side of the second sub-display panel faces the third side of the second sub-display panel.

17. An electronic device comprising a display device for providing a display screen, wherein the display device comprises:
a main display panel comprising a wafer-based substrate;
at least one sub-display panel comprising a glass-based substrate and adjacent to the main display panel;
a first pixel arranged in a display area of the main display panel, the first pixel includes a source-follower pixel circuit; and
a second pixel arranged in a display area of the sub-display panel, the second pixel includes a diode-connected pixel circuit, the second pixel having a size larger than the first pixel.

18. The electronic device of claim 17, wherein a number of transistors of the second pixel is greater than a number of transistors of the first pixel.

19. The electronic device of claim 18, wherein
the transistors of the first pixel comprise a first transistor which is a driving transistor of the first pixel,
the transistors of the second pixel comprise a first transistor which is a driving transistor of the second pixel,
the first transistor of the first pixel is connected to another transistor of the first pixel in a source-follower configuration, and
the first transistor of the second pixel is connected to another transistor of the second pixel in a diode-connected configuration.

20. The electronic device of claim 17, wherein the electronic device comprises a smartphone, a tablet, a laptop computer, a TV, a monitor, smart glasses, a smart watch, a head-mounted display, and a display for vehicles.
